(19) United States
(12) Patent Application Publication
(10) Pub. No.: US 2026/0075876 A1
(43) Pub. Date: Mar. 12, 2026

(54) NANOSHEET DEVICE BACKSIDE CONNECTING TO BOTH VDD AND VSS AT THE SAME LEVEL

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Min Gyu Sung, Latham, NY (US)

(21) Appl. No.: 18/829,737

(22) Filed: Sep. 10, 2024

(51) Int. Cl. H01L 29/417; H01L 23/528; H01L 27/088; H01L 29/06; H01L 29/423; H01L 29/775; H01L 29/786

(52) U.S. Cl. CPC H10D 30/6729; H10D 84/83; H10W 20/43; H10D 30/43; H10D 30/6735; H10D 30/6757; H10D 62/121

(57) ABSTRACT

A microelectronic structure includes a first nanosheet FET that includes a first and second source/drain. A second nanosheet FET located adjacent to the first nanosheet FET. A first backside contact connected to the first source/drain and the first backside contact extends through the backside region of the second nanosheet FET. A second backside contact connected to the second source/drain. The first backside contact and the second backside contact are located on the same level.

### BACKGROUND

The present invention generally relates to the field of microelectronics, and more particularly to forming connections to power rails located on the same level.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form connections to power rails without forcing the connections to extend over multiple levels.

### BRIEF SUMMARY

Additional aspects and/or advantages will be set forth in part in the description which follows and, in part, will be apparent from the description, or may be learned by practice of the invention.

A microelectronic structure includes a first nanosheet FET that includes a first and second source/drain. A second nanosheet FET located adjacent to the first nanosheet FET. A first backside contact connected to the first source/drain and the first backside contact extends through the backside region of the second nanosheet FET. A second backside contact connected to the second source/drain. The first backside contact and the second backside contact are located on the same level.

A microelectronic structure includes a first nanosheet FET that includes a first and second source/drain. A second nanosheet FET located adjacent to the first nanosheet FET. A first backside contact connected to the first source/drain and the first backside contact extends through the backside region of the second nanosheet FET. A second backside contact connected to the second source/drain. The first backside contact and the second backside contact are located on the same level. A dielectric pillar located between the first backside contact 200 and the second backside contact.

A microelectronic structure includes a first nanosheet FET that includes a first and second source/drain. A second nanosheet FET located adjacent to the first nanosheet FET includes a third source/drain. A dielectric cap is located on the backside of the third source/drain. A first backside contact connected to the first source/drain 130 and the first backside contact extends through the backside region of the second nanosheet FET. A second backside contact connected to the second source/drain. The first backside contact and the second backside contact are located on the same level. A dielectric pillar located between the first backside contact and the second backside contact.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X1 of the first nanosheet FET after initial frontside processing, in accordance with the embodiment of the present invention.

FIG. 3 illustrates a cross section X2 of the second nanosheet FET after initial frontside processing, in accordance with the embodiment of the present invention.

FIG. 4 illustrates a cross section Y1 of the source/drain region after initial frontside processing, in accordance with the embodiment of the present invention.

FIG. 5 illustrates a cross section X1 of the first nanosheet FET after flipping the device over and initial backside processing, in accordance with the embodiment of the present invention.

FIG. 6 illustrates a cross section X2 of the second nanosheet FET after flipping the device over and initial backside processing, in accordance with the embodiment of the present invention.

FIG. 7 illustrates a cross section Y1 of the source/drain region after flipping the device over and initial backside processing, in accordance with the embodiment of the present invention.

FIG. 8 illustrates a top-down view of a plurality of nanosheet transistors that illustrates the formation of the backside multi-direction trench and a straight trench, in accordance with the embodiment of the present invention.

FIG. 9 illustrates a cross section X1 of the first nanosheet FET after the formation of the backside multi-direction trench and a straight trench, in accordance with the embodiment of the present invention.

FIG. 10 illustrates a cross section X2 of the second nanosheet FET after the formation of the backside multi-direction trench and a straight trench, in accordance with the embodiment of the present invention.

FIG. 11 illustrates a cross section Y1 of the source/drain region after the formation of the backside multi-direction trench and a straight trench, in accordance with the embodiment of the present invention.

FIG. 12 illustrates a cross section Y2 of a second source/drain region after the formation of the backside multi-direction trench and a straight trench, in accordance with the embodiment of the present invention.

FIG. 13 illustrates a cross section X1 of the first nanosheet FET after removal of the exposed placeholders, in accordance with the embodiment of the present invention.

FIG. 14 illustrates a cross section X2 of the second nanosheet FET after removal of the exposed placeholders, in accordance with the embodiment of the present invention.

FIG. 15 illustrates a cross section Y1 of the source/drain region after removal of the exposed placeholders, in accordance with the embodiment of the present invention.

FIG. 16 illustrates a cross section Y2 of a second source/drain region after removal of the exposed placeholders, in accordance with the embodiment of the present invention.

FIG. 17 illustrates a cross section X1 of the first nanosheet FET after formation and patterning of a lithography layer and formation of a backside isolation layer, in accordance with the embodiment of the present invention.

FIG. 18 illustrates a cross section X2 of the second nanosheet FET after formation and patterning of a lithography layer and formation of a backside isolation layer, in accordance with the embodiment of the present invention.

FIG. 19 illustrates a cross section Y1 of the source/drain region after formation and patterning of a lithography layer and formation of a backside isolation layer, in accordance with the embodiment of the present invention.

FIG. 20 illustrates a cross section Y2 of a second source/drain region after formation and patterning of a lithography layer and formation of a backside isolation layer, in accordance with the embodiment of the present invention.

FIG. 21 illustrates a top-down view of a plurality of nanosheet transistors that illustrates the formation of the multi-direction shared contact and formation of the straight contact, in accordance with the embodiment of the present invention.

FIG. 22 illustrates a cross section X1 of the first nanosheet FET after formation of multi-direction shared contact and formation of the straight contact, in accordance with the embodiment of the present invention.

FIG. 23 illustrates a cross section X2 of the second nanosheet FET after formation of multi-direction shared contact and formation of the straight contact, in accordance with the embodiment of the present invention.

FIG. 24 illustrates a cross section Y1 of the source/drain region after formation of multi-direction shared contact and formation of the straight contact, in accordance with the embodiment of the present invention.

FIG. 25 illustrates a cross section Y2 of a second source/drain region after formation of multi-direction shared contact and formation of the straight contact, in accordance with the embodiment of the present invention.

FIG. 26 illustrates a cross section X1 of the first nanosheet FET after formation of a shared contact cut, in accordance with the embodiment of the present invention.

FIG. 27 illustrates a cross section X1 of the first nanosheet FET after increasing the height of the backside interlayer dielectric layer and formation of a plurality of contact vias, in accordance with the embodiment of the present invention.

FIG. 28 illustrates a cross section X2 of the second nanosheet FET after increasing the height of the backside interlayer dielectric layer and formation of a plurality of contact vias, in accordance with the embodiment of the present invention.

FIG. 29 illustrates a cross section Y1 of the source/drain region after increasing the height of the backside interlayer dielectric layer and formation of a plurality of contact vias, in accordance with the embodiment of the present invention.

FIG. 30 illustrates a cross section Y2 of a second source/drain region after increasing the height of the backside interlayer dielectric layer and formation of a plurality of contact vias, in accordance with the embodiment of the present invention.

FIG. 31 illustrates a cross section X1 of the first nanosheet FET after increasing the height of the backside interlayer dielectric layer, formation of a first and second metal line, and formation of a backside interconnect, in accordance with the embodiment of the present invention.

FIG. 32 illustrates a cross section X2 of the second nanosheet FET after increasing the height of the backside interlayer dielectric layer, formation of a first and second metal line, and formation of a backside interconnect, in accordance with the embodiment of the present invention.

FIG. 33 illustrates a cross section Y1 of the source/drain region after increasing the height of the backside interlayer dielectric layer, formation of a first and second metal line, and formation of a backside interconnect, in accordance with the embodiment of the present invention.

FIG. 34 illustrates a cross section Y2 of a second source/drain region after increasing the height of the backside interlayer dielectric layer, formation of a first and second metal line, and formation of a backside interconnect, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed to a first nanosheet FET and a second nanosheet FET that includes a first backside contact that connects to a first power rail adjacent to the first nanosheet FET and a second backside contact that connects to a second power rail adjacent to the second nanosheet FET. The first and second power rails are located on the same level. The first and second backside contacts are located on the same level. The second backside contact extends through the backside region of the second nanosheet FET and bypasses the second nanosheet FET towards the second power rail.

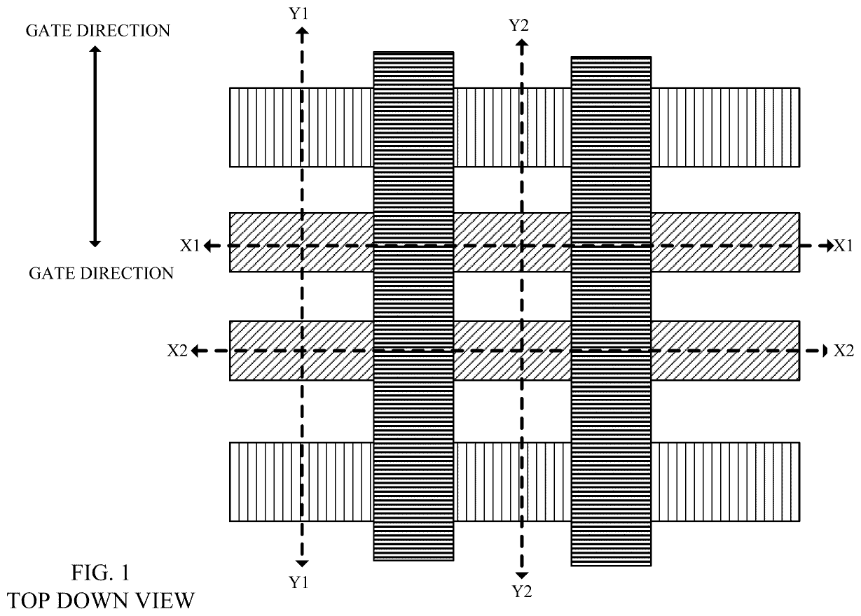

FIG. 1 illustrates a top-down view of multiple devices, in accordance with the embodiment of the present invention. Cross-section X1 is a cross-section that extends through the first nanosheet FET. Cross-section X2 is a cross-section that extends through the second nanosheet FET. Cross-section Y1 is a cross-section through a first source/drain region that spans across the first and second nanosheet transistors or field-effect-transistors. Cross-section Y2 is a cross-section through a second source/drain region that spans across the first and second nanosheet transistors or field-effect-transistors. Cross-sections X1 and X2 are perpendicular to the gate direction and cross-section Y1 and Y2 are parallel to the gate direction.

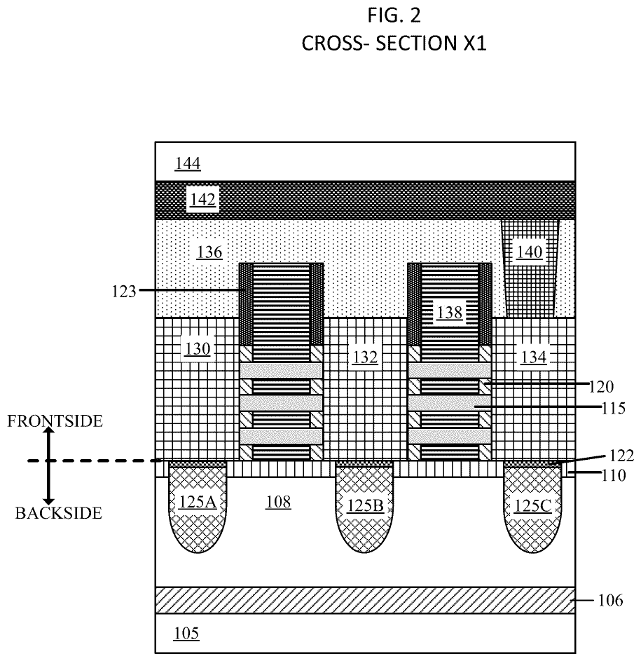

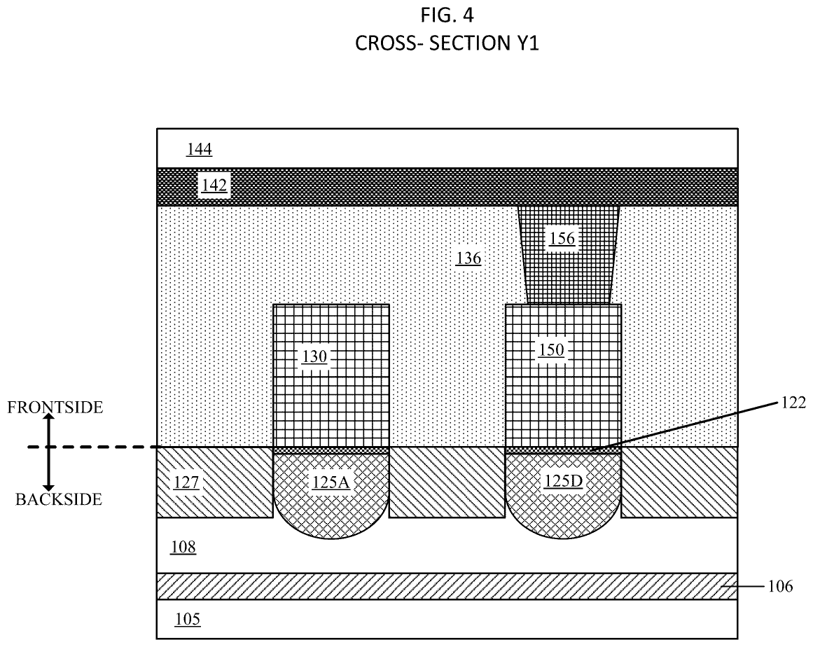

Referring now to FIGS. 2, 3, and 4, illustrate a structure is shown during an intermediate step of a method of fabrication after initial frontside processing. FIG. 2 illustrate a cross-section of the first nanosheet FET that includes a first substrate 105, an etch stop 106, a second substrate 108, a bottom dielectric isolation layer 110, a first placeholder 125A, a second placeholder 125B, a third placeholder 125C, an intermediate layer 122, a plurality of channel layers 115, inner spacers 120, a first source/drain 130, a second source/drain 132, a third source/drain 134, gate 138, gate spacer 123, a frontside interlayer dielectric layer 136, a first frontside source/drain contact 140, a frontside interconnect 142, and a carrier wafer 144.

The first substrate 105 and the second substrate 108 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor first substrate 105 and the second substrate 108 may be doped, undoped or contain doped regions and undoped regions therein. Gate 138 can be comprised of, for example, a gate dielectric liner, such as high-k dielectric like HfO₂, ZrO₂, HfLaOₓ, etc., and work function layers, such as TiN, TiAlC, TiC, etc., and conductive metal fills, like W.

The first source/drain 130, the second source/drain 132, and the third source/drain 134, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

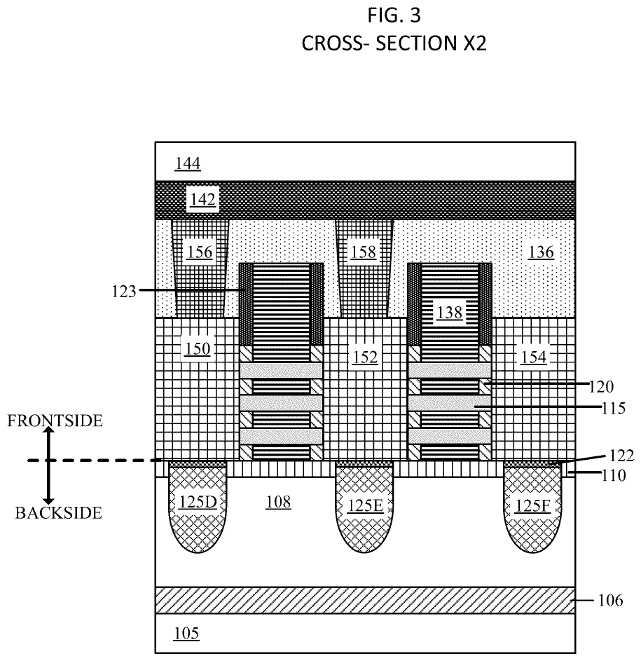

The first frontside source/drain contact 140 is connected to the frontside surface of the third source/drain 134. FIG. 3 illustrates a cross section of the second nanosheet FET that includes many of the same components (utilizing the same reference numbers) as the first nanosheet FET as illustrated in FIG. 2. FIG. 3 further includes a fourth placeholder 125D, a fifth placeholder 125E, a sixth placeholder 125F, a fourth source/drain 150, a fifth source/drain 152, a sixth source/drain 154, a second frontside source/drain contact 156, and a third frontside source/drain contact 158. The second frontside source/drain contact 156 is connected to a frontside surface of the fourth source/drain 150 and the third frontside source/drain contact 158 is connected to a frontside surface of the fifth source/drain 152. The frontside interconnect 142 is located on top of the frontside interlayer dielectric layer 136, the first, second, and third frontside source/drain contacts 140, 156, 158. The frontside interconnect 142 is also referred to as the back-end-of-the-line (BEOL) layer, which can include one or more layers/levels, one or more metal lines, and one or more connecting vias. The carrier wafer 144 is located on top of the frontside interconnect 142.

The fourth source/drain 150, the fifth source/drain 152, and the sixth source/drain 154, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

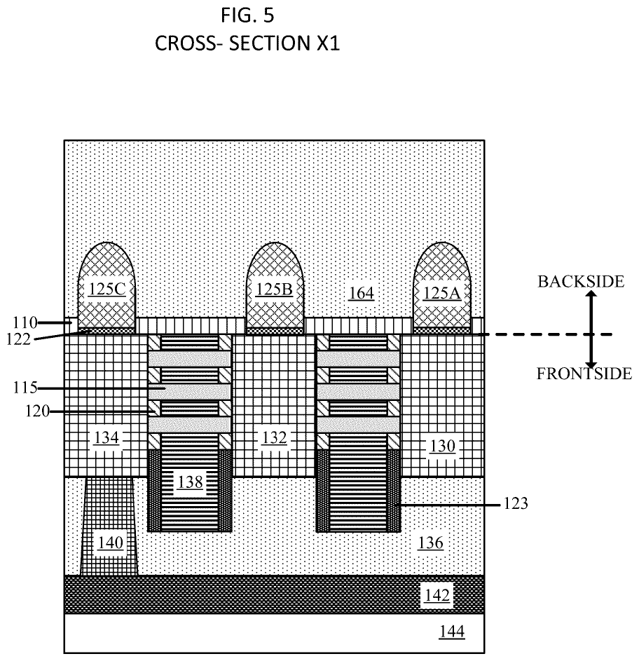

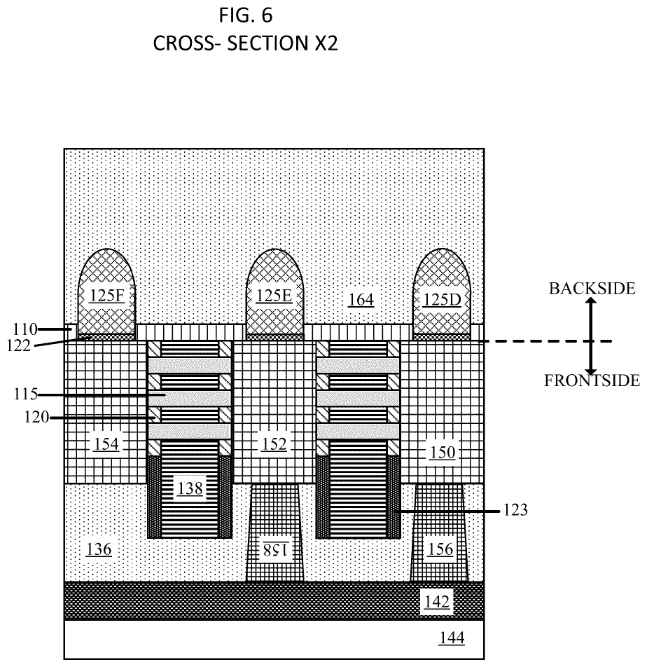

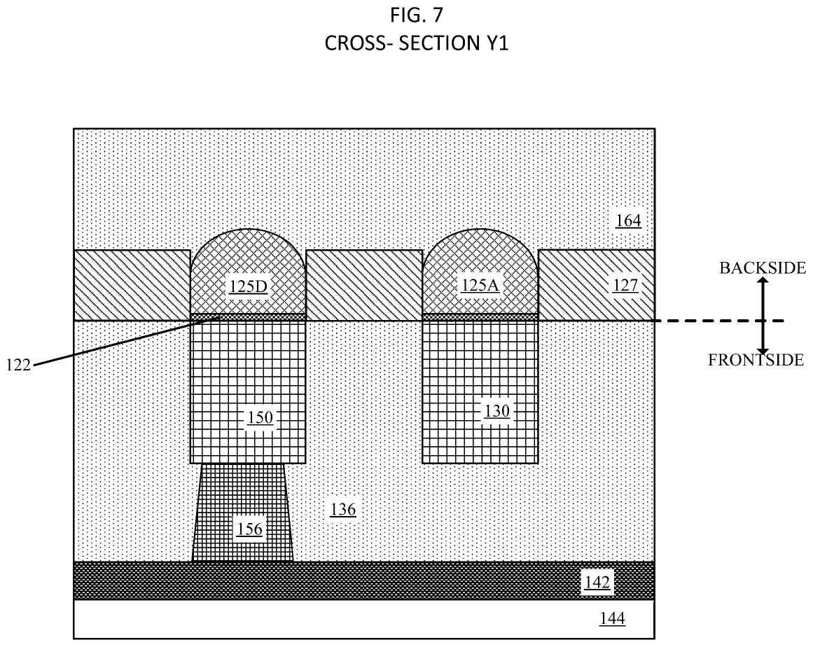

FIGS. 5, 6, and 7 illustrate the processing stage after flipping the device over and initial backside processing. The nanosheet FETs are flipped over for backside processing. The first substrate 105, the etch stop 106, and the second substrate 108 are removed. The removal of these layers expose the backside surface of the bottom dielectric isolation layer 110 and the placeholders 125A, 125B, 125C, 125D, 125E, and 125F. A backside interlayer dielectric layer 164 is formed on the backside region of the first and second nanosheet FETs, such that, the backside interlayer dielectric layer 164 is formed on the backside surface of the bottom dielectric isolation layer 110 and around the exposed placeholders 125A, 125B, 125C, 125D, 125E, and 125F.

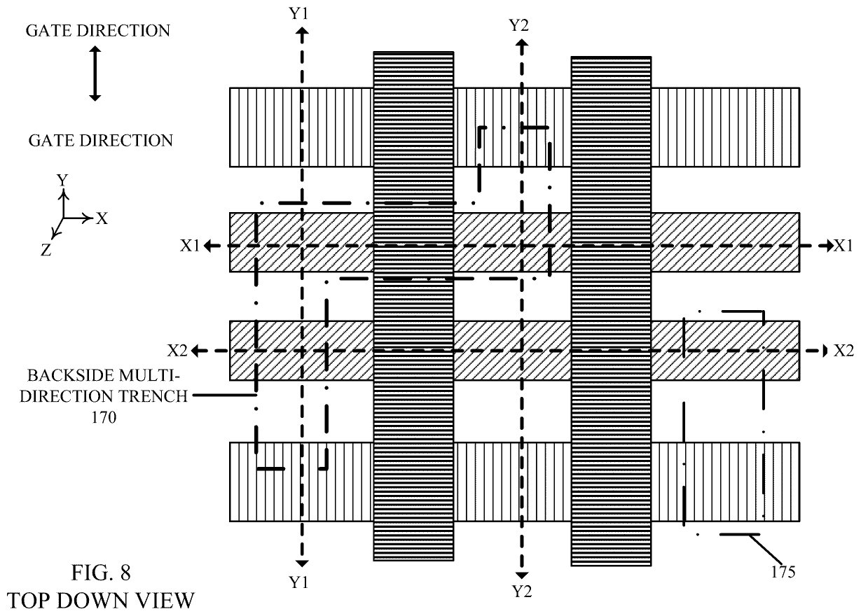

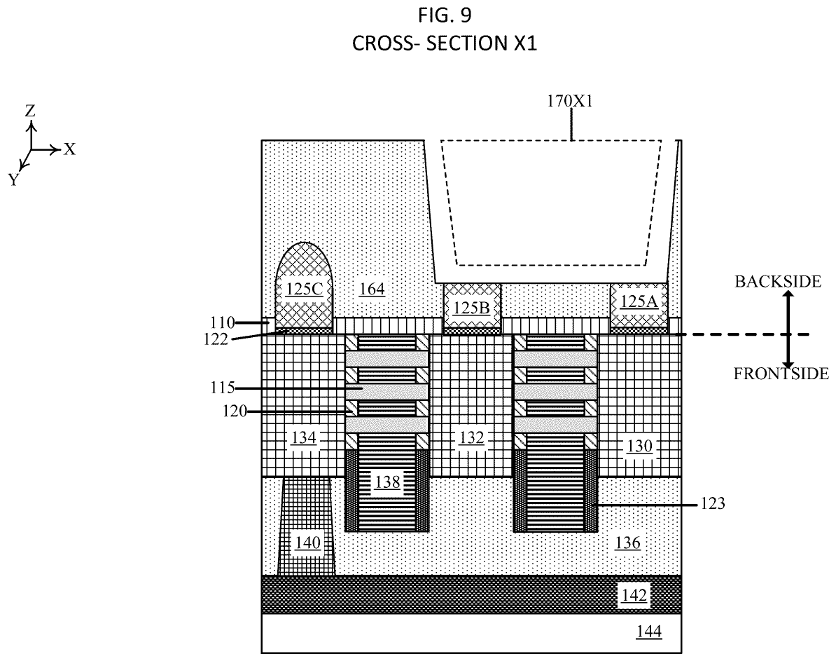

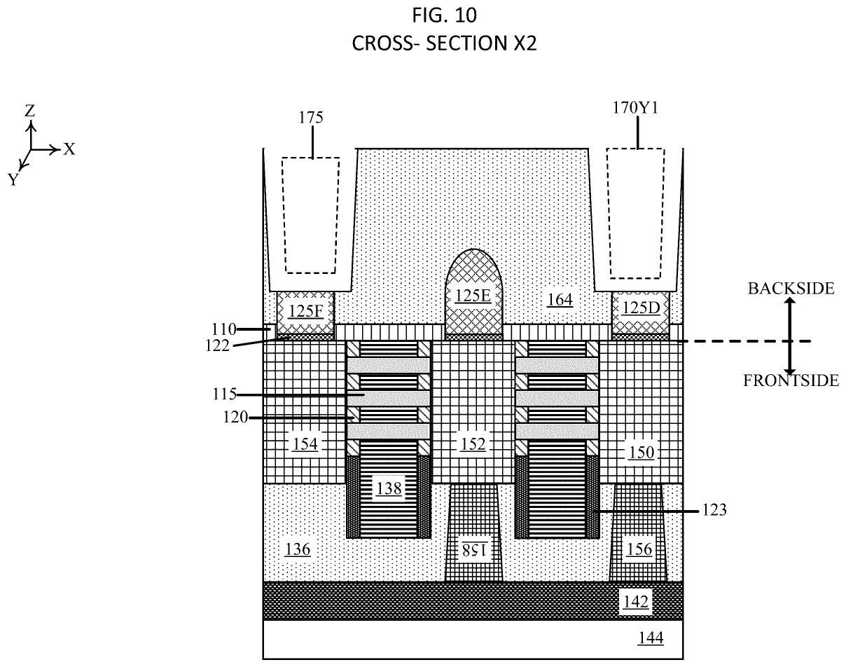

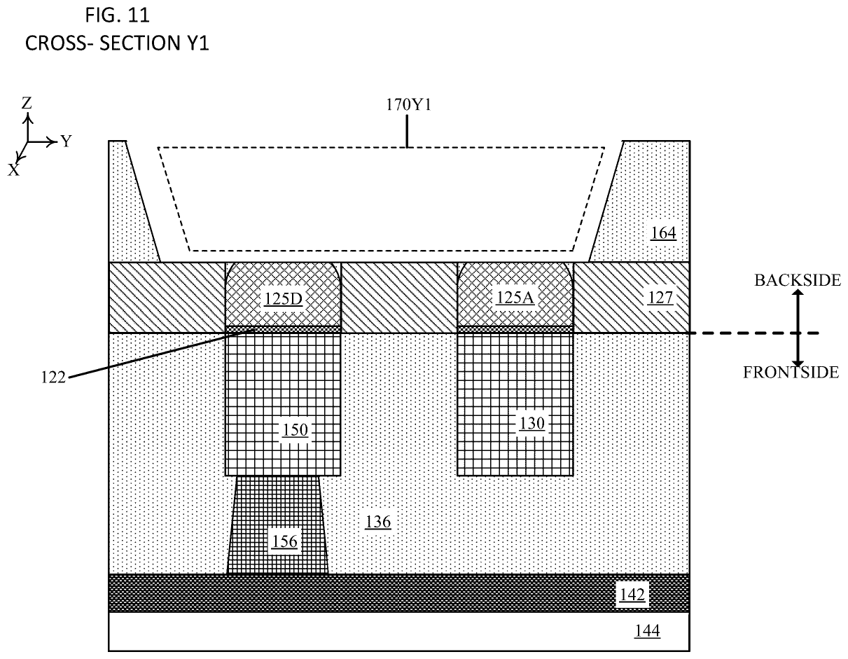

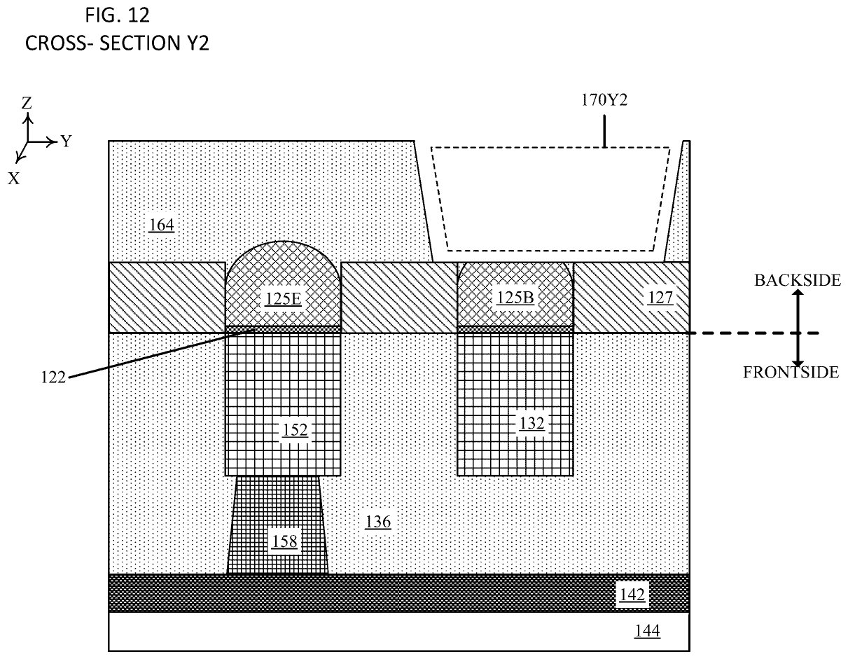

FIGS. 8, 9, 10, 11, and 12 illustrate the processing stage after the formation of the backside multi-direction trench 170 and a straight trench 175. A backside multi-direction trench 170 and a straight trench 175 are formed in the backside interlayer dielectric layer 164. FIG. 8 illustrates a top-down view from the frontside perspective, where the dashed multi-branched box represents the multi-direction trench 170 and the straight dashed box represent the straight trench 175. Straight trench 175 exposes the sixth placeholder 125F, see for example, FIG. 10, and extends along the Y direction as indicated in FIG. 8. The backside multi-direction trench 170 is comprised of multiple connecting paths or trenches as illustrated in FIG. 8. FIG. 9 illustrates a section of the backside multi-direction trench 170 that extends along cross-section X1, herein after this section of the backside multi-direction trench 170 will be referred to as the perpendicular trench 170X1. Perpendicular trench 170X1 is named because the trench/path extends perpendicular to the gate direction. Perpendicular trench 170X1 exposes the first placeholder 125A and the second placeholder 125B. FIG. 11 illustrates a section of the backside multi-direction trench 170 that extends through the first source/drain region, e.g., cross-section Y1, hereinafter this section of the backside multi-direction trench 170 will be referred to as the first source/drain trench 170Y1. The first source/drain trench 170Y1 exposes the first placeholder 125A and the fourth placeholder 125D. Perpendicular trench 170X1 and the first source/drain trench 170Y1 overlap each other around the backside region of the first placeholder 125A. FIG. 12 illustrates a section of the backside multi-direction trench 170 that extends through the second source/drain region, e.g., cross-section Y2, hereinafter this section of the backside multi-direction trench 170 will be referred to as the second source/drain trench 170Y2. The second source/drain trench 170Y2 exposes the second placeholder 125B. Perpendicular trench 170X1 and the second source/drain trench 170Y2 overlap each other around the backside region of the second placeholder 125B. FIG. 10 illustrates cross-section X2 that shows a portion of the first source/drain trench 170Y1 and a portion of the straight trench 175. The multi-direction trench 170 and the straight trench 175 are located on the same level in the backside region of the first and second nanosheet FETs.

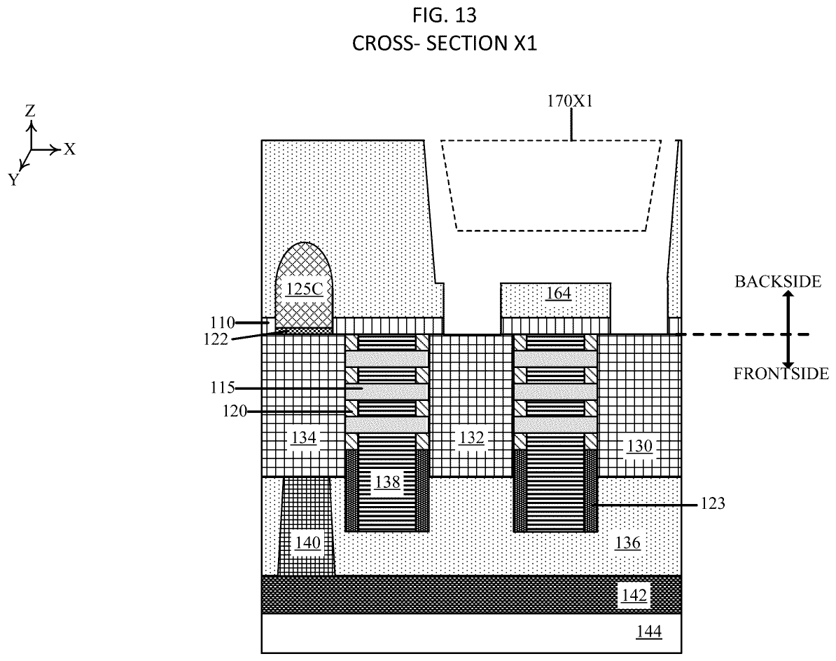

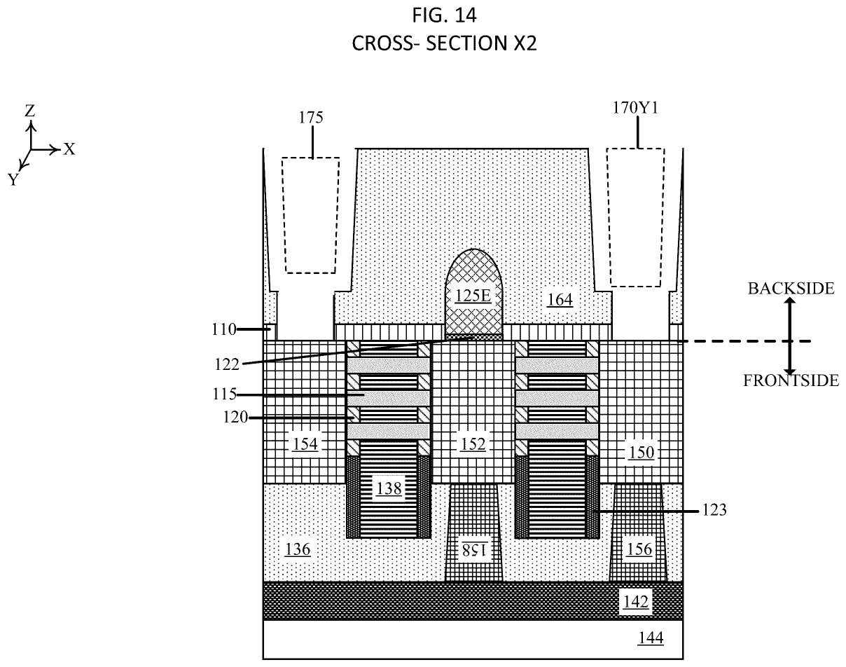

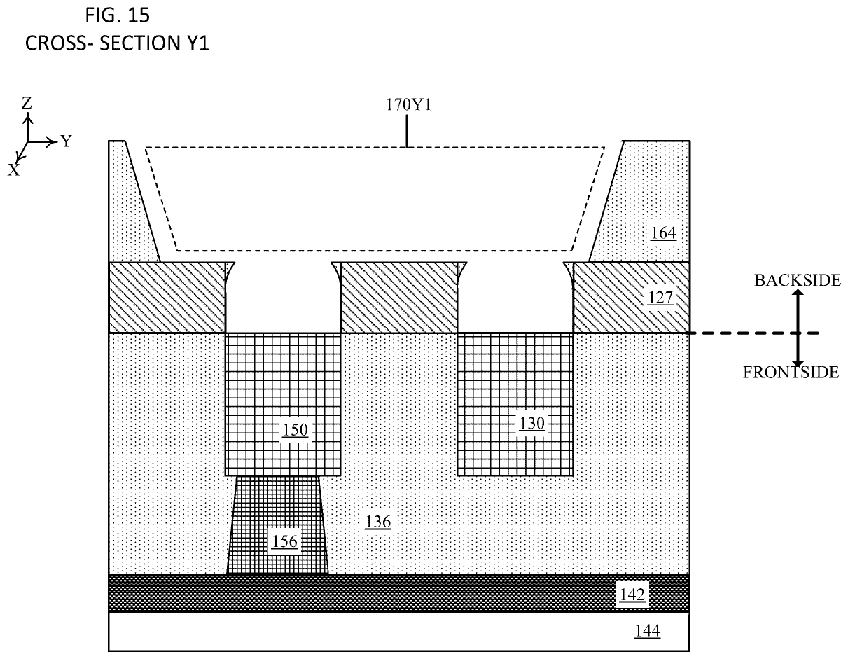

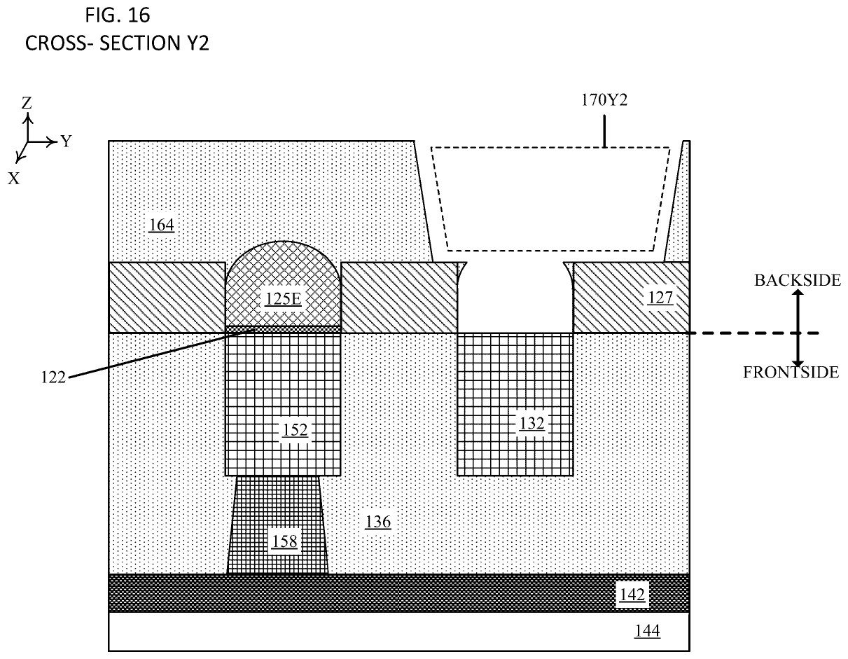

FIGS. 13, 14, 15, and 16 illustrate the processing stage after removal of the exposed placeholders 125A, 125B, 125D, and 125F. The first placeholder 125A, the second placeholder 125B, the fourth placeholder 125D, the sixth placeholder 125F, and the intermediate layer 122 are removed. The removal of the second placeholder 125B and the intermediate layer 122 exposed the backside of the second source/drain 132, see, for example, FIGS. 13 and 16. The backside surface of the second source/drain 132 is exposed to the perpendicular trench 170X1 and the second source/drain trench 170Y1. The removal of the first placeholder 125A, the fourth placeholder 125D, and the intermediate layer 122 exposed the backside of the first source/drain 130, and the fourth source/drain 150 to the first source/drain trench 170Y1, see, for example, FIGS. 13, 14 and 15. The backside surface of the first source/drain 130 is exposed to the perpendicular trench 170X1. The removal of the sixth placeholder 125F and the intermediate layer 122 exposes the backside of the sixth source/drain 154 to the straight trench 175.

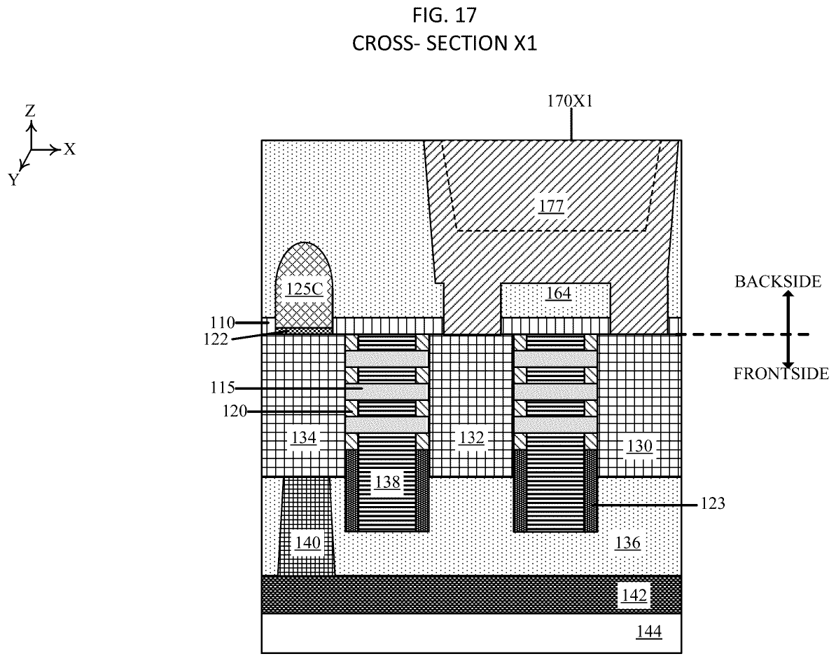

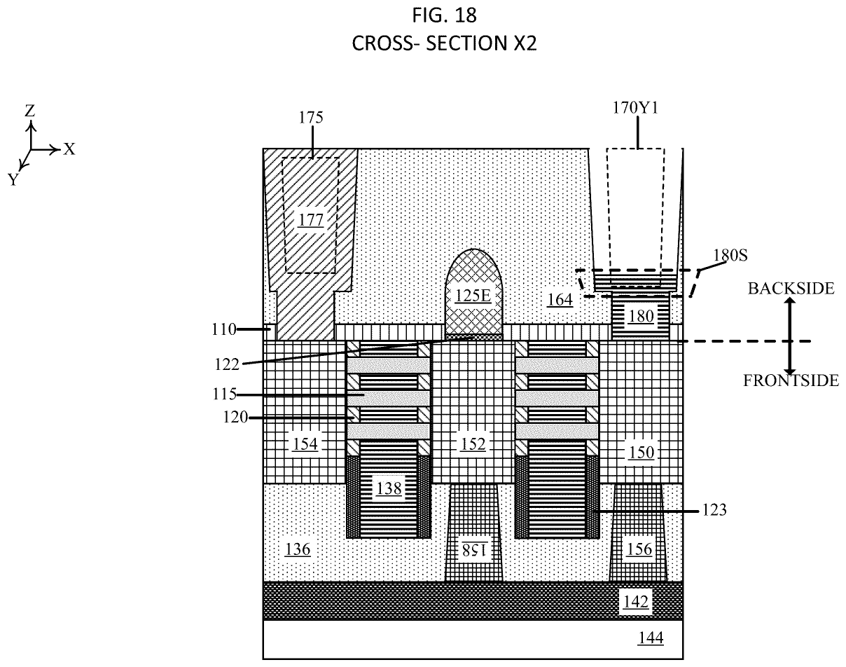

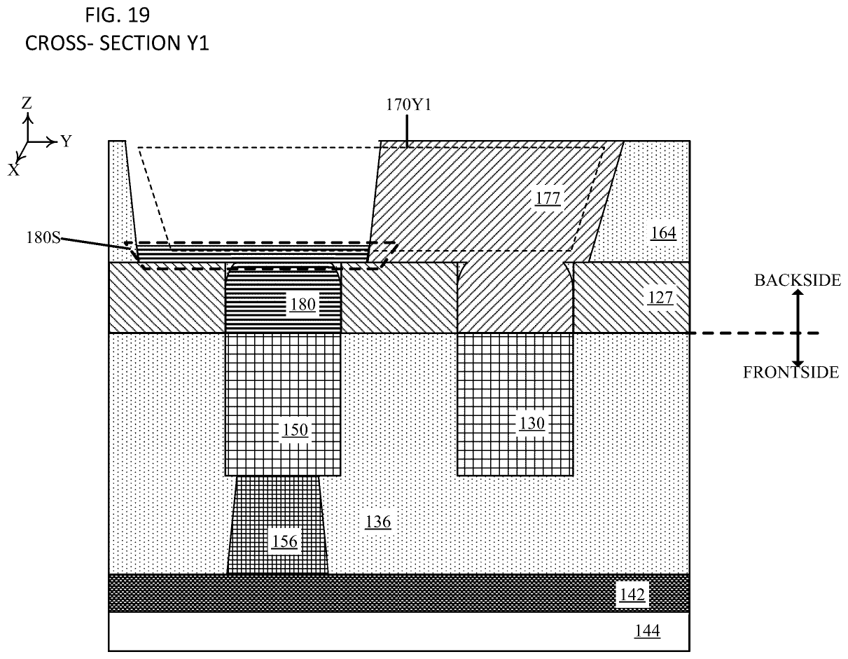

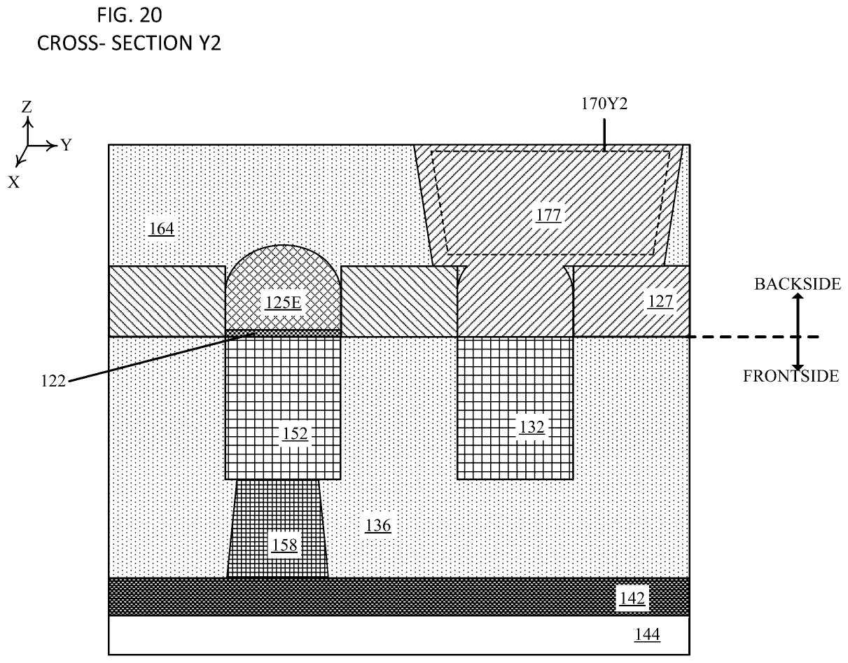

FIGS. 17, 18, 19, and 20 illustrate the processing stage after formation and patterning of a lithography layer 177 and formation of a backside isolation layer 180. A lithography layer 177 is formed within the backside multi-direction trench 170 and within the straight trench 175. Lithography layer 177 is patterned to remove portions of the lithography layer 177 to expose the underlying component (for example, fourth source/drain 150). FIGS. 17-20 illustrate the example where the lithography layer 177 exposes the backside of the fourth source/drain 150. The fourth source/drain 150 is exposed because the second frontside source/drain contact 156 is connected to the frontside surface of the fourth source/drain 150. A backside isolation layer 180 is formed on the backside surface of the fourth source/drain 150. The backside isolation layer 180 prevents any material from connecting to the backside surface of the fourth source/drain 150. The backside isolation layer 180 includes a wider portion or step 180S that extends into the first source/drain trench 170Y1.

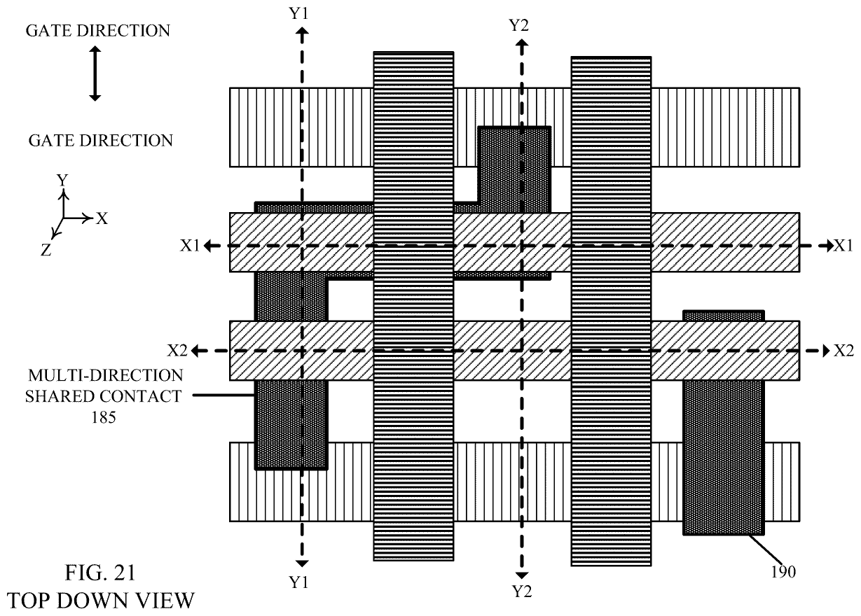

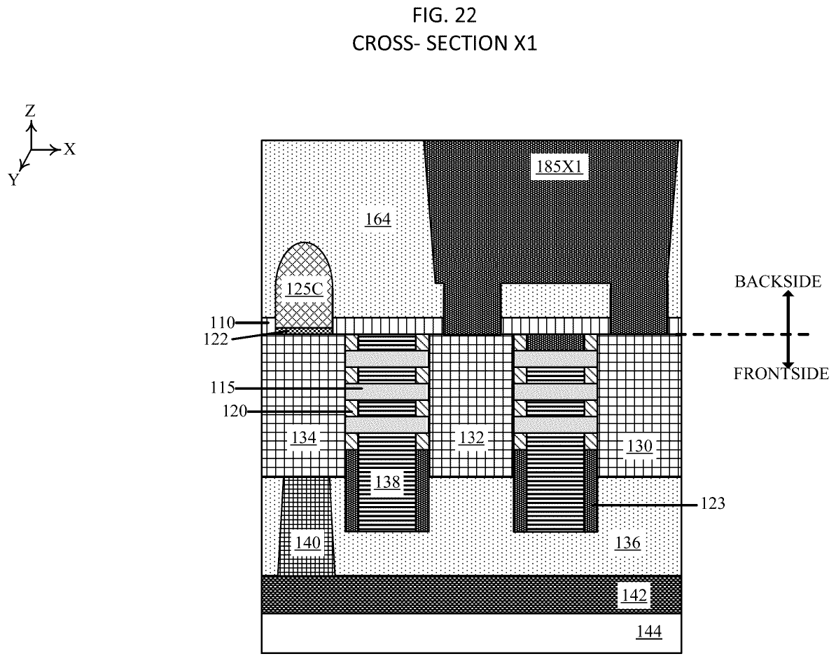

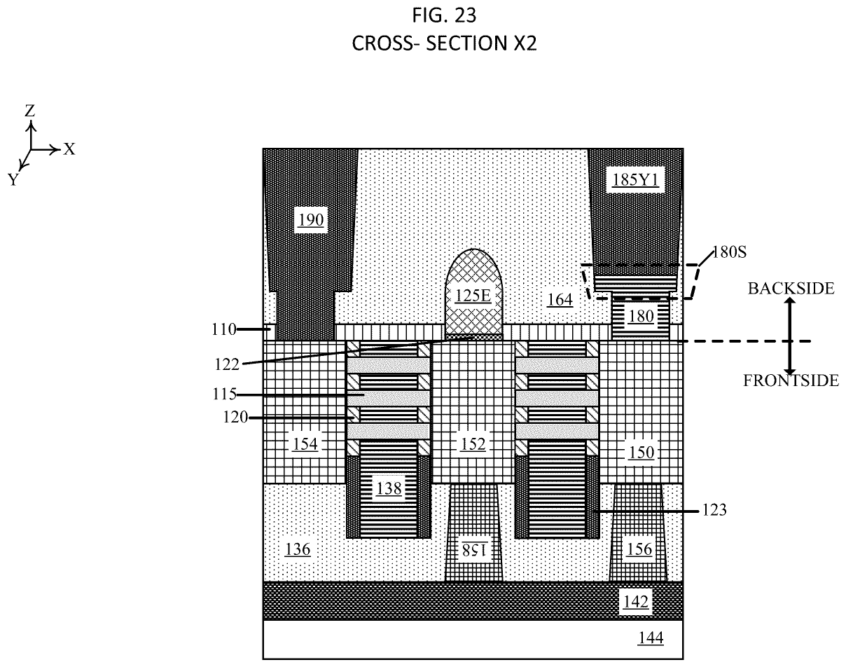

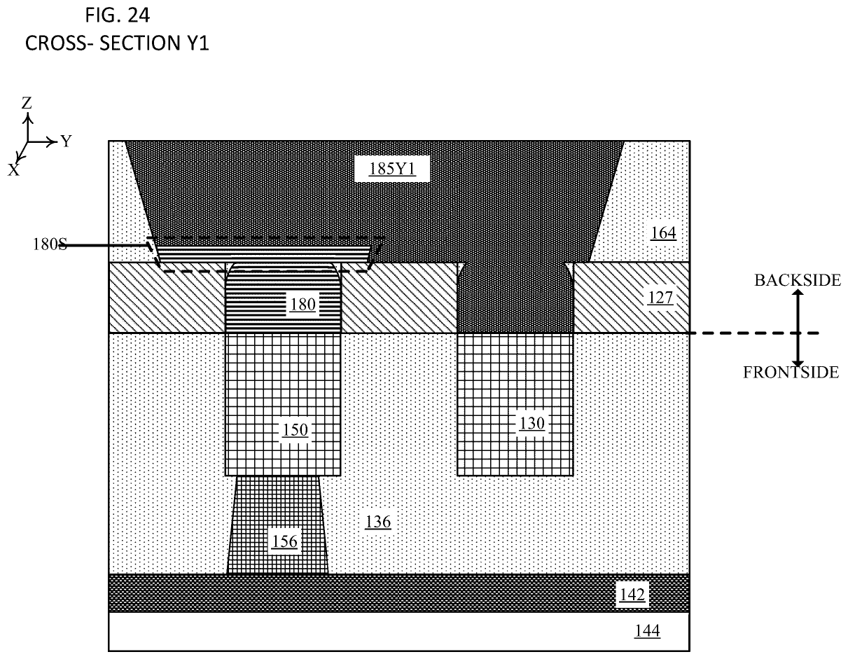

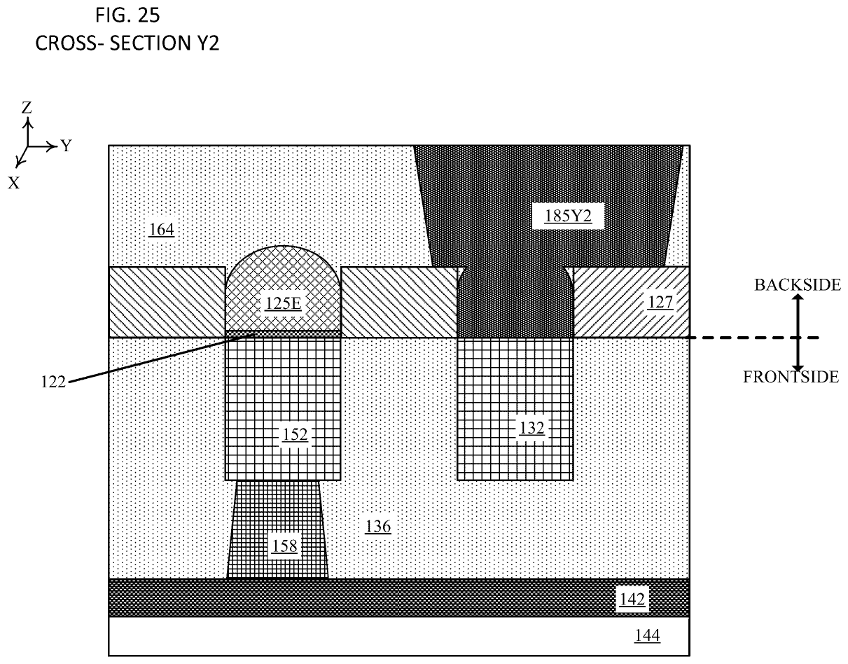

FIGS. 21, 22, 23, 24, and 25 illustrate the processing stage after formation of multi-direction shared contact 185 and formation of the straight contact 190. A metallization process is utilized to fill the backside multi-direction trench 170 and the straight trench 175 with a conductive metal to from the multi-direction shared contact 185 and the straight contact 190. FIG. 21 illustrates a top-down view from the frontside perspective of how the multi-direction shared contact 185 extends across the first and second nanosheet FETs and how they extend to the adjacent metal lines, which will be described in further detail below. FIG. 22 illustrates a section of the multi-direction shared contact 185 that extends along cross-section X1, herein after this section of the multi-direction shared contact 185 will be referred to as the perpendicular contact 185X1. Perpendicular contact 185X1 is named because the contact extends perpendicular to the gate direction. Perpendicular contact 185X1 is in contact with a backside surface of the first source/drain 130 and in contact with a backside surface of the second source/drain 132. FIG. 23 illustrates a section of the straight contact 190 that is in contact with the sixth source/drain 154. FIG. 23 further illustrates a section of the multi-direction shared contact 185 that extends in the first source/drain region and is in contact with the backside isolation layer 180. This section of the multi-direction shared contact 185 will be referred to as the backside first source/drain bypass 185Y1. The backside first source/drain bypass 185Y1 has a step that is in contact with the step 180S of the backside isolation layer 180. FIG. 24 illustrates a section of the multi-direction shared contact 185 that is located in the first source/drain region. This section of the multi-direction shared contact 185 includes a part of perpendicular contact 185X1 where it overlaps with the first source/drain bypass 185Y1. The first source/drain contact bypass 185Y1 is in contact with the first source/drain 130 and bypass the fourth source/drain 150. The backside isolation layer 180, 180S prevents the first source/drain contact bypass 185Y1 from contacting the fourth source/drain 150. FIG. 25 illustrates a section of the multi-direction shared contact 185 that extends in the second source/drain region, hereinafter will be referred to as second source/drain contact 185Y2. The second source/drain contact 185Y2 is in contact with the backside surface of the second source/drain 132. The first source/drain contact bypass 185Y1 and the second source/drain contact 185Y2 are located on the same level.

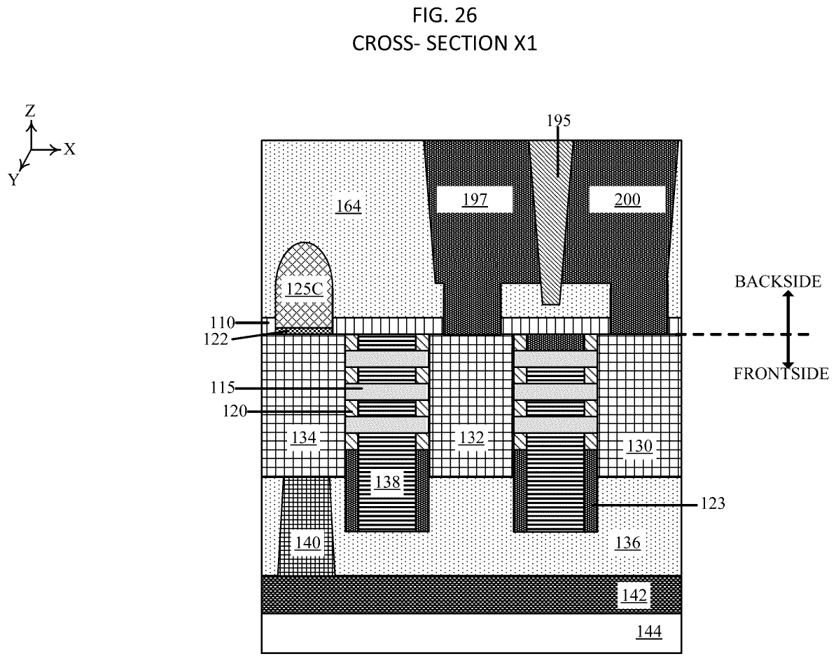

FIG. 26 illustrates the processing stage after formation of a shared contact cut 195. A trench (not shown) is formed in the multi-direction share contact 185. The trench (not shown) is located in the perpendicular contact 185X1, specifically, the trench (not shown) is located between the first source/drain 130 and the second source/drain 132. This trench (not shown) is filled with a dielectric material to form the shared contact cut 195. The shared contact cut 195 separates the multi-direction shared contact 185 into separate contacts, specifically, the first source/drain bypass contact 200, and the second source/drain contact 197. The first source/drain bypass contact 200 and the second source/drain contact 197 are isolated from each other and are located on the same level.

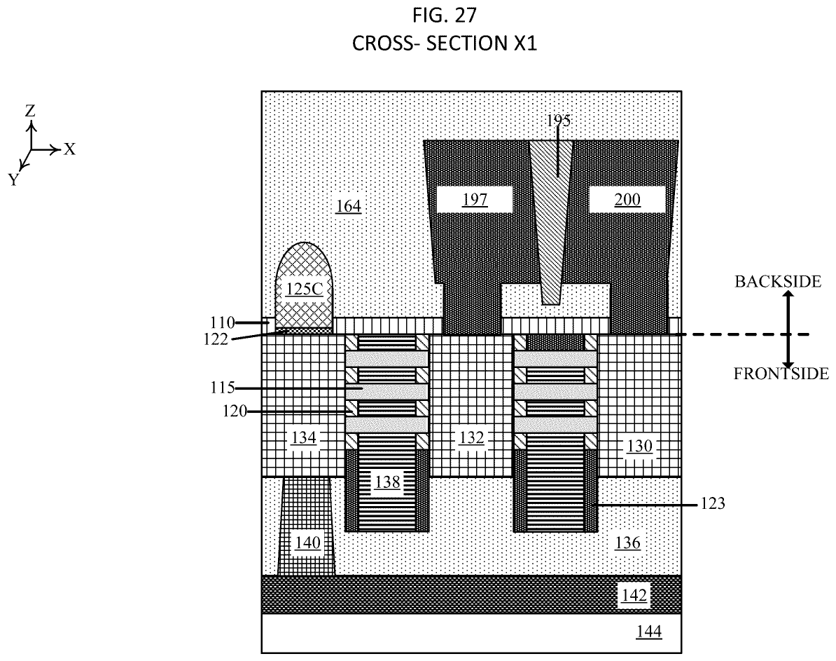

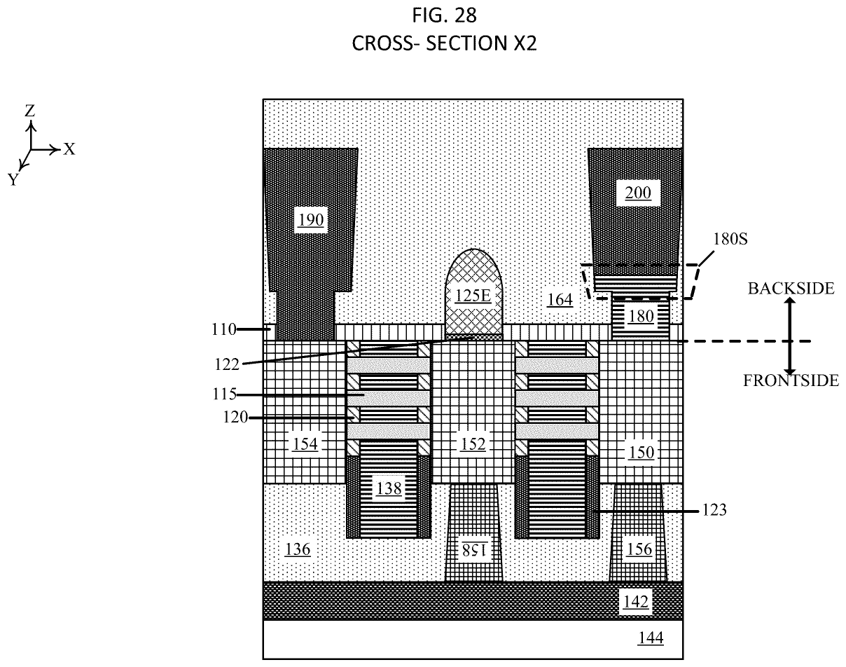

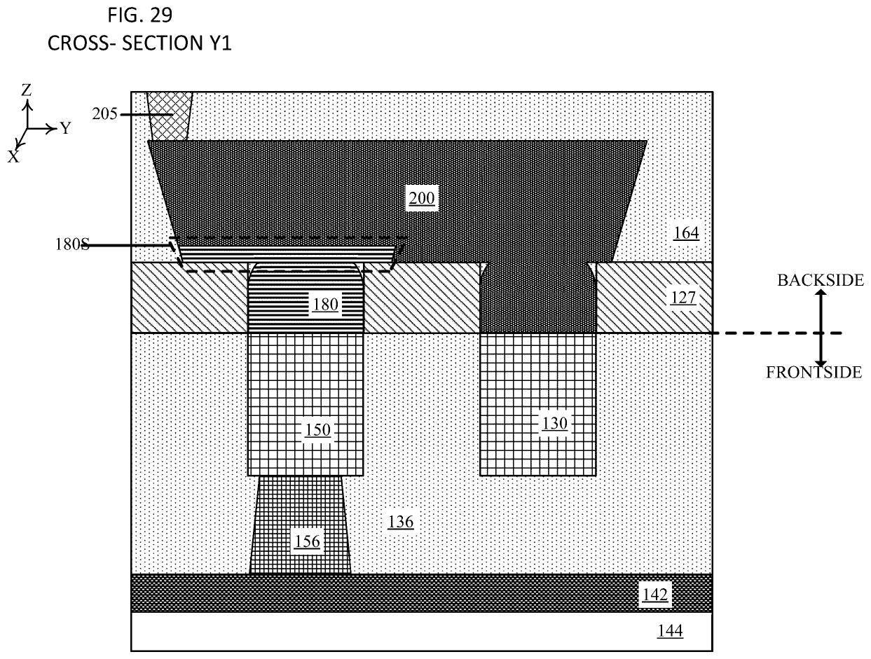

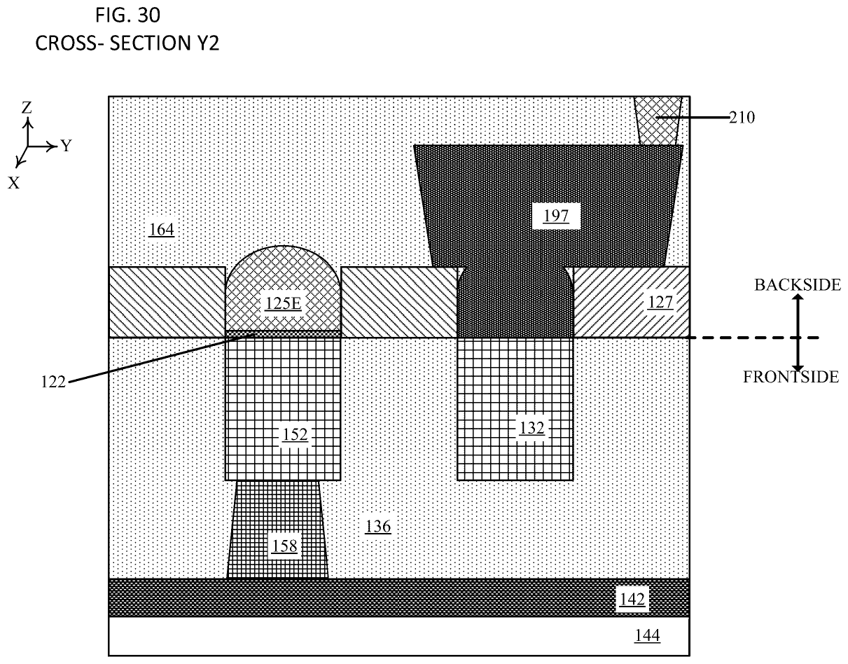

FIGS. 27, 28, 29, and 30 illustrate the processing stage after increasing the height of the backside interlayer dielectric layer 164 and formation of a plurality of contact vias 205, 210. The height of the backside interlayer dielectric layer 164 is increased so that the backside interlayer dielectric layer 164 extends on top of the straight contact 190, the second source/drain contact 197, and the first source/drain bypass contact 200. A plurality of trenches (not shown) are formed in the backside interlayer dielectric layer 164, where each of the trenches (not shown) exposes a surface of one of the backside contacts (i.e., the straight contact 190, the second source/drain contact 197, and the first source/drain bypass contact 200). A metallization process is utilized to fill these trenches to form a first contact via (not shown), a second contact via 205, and third contact via 210. The first contact via (not shown) is connected to the straight contact 190. The second contact via 205 is connected to the first source/drain bypass contact 200. The second contact via 205 is located at position where a metal line will be formed that will be adjacent to the second nanosheet FET which will be described in further detail below. The third contact via 210 is connected to the second source/drain contact 197, where the third contact via 210 will be located where the first metal line will be located adjacent to the first nanosheet FET.

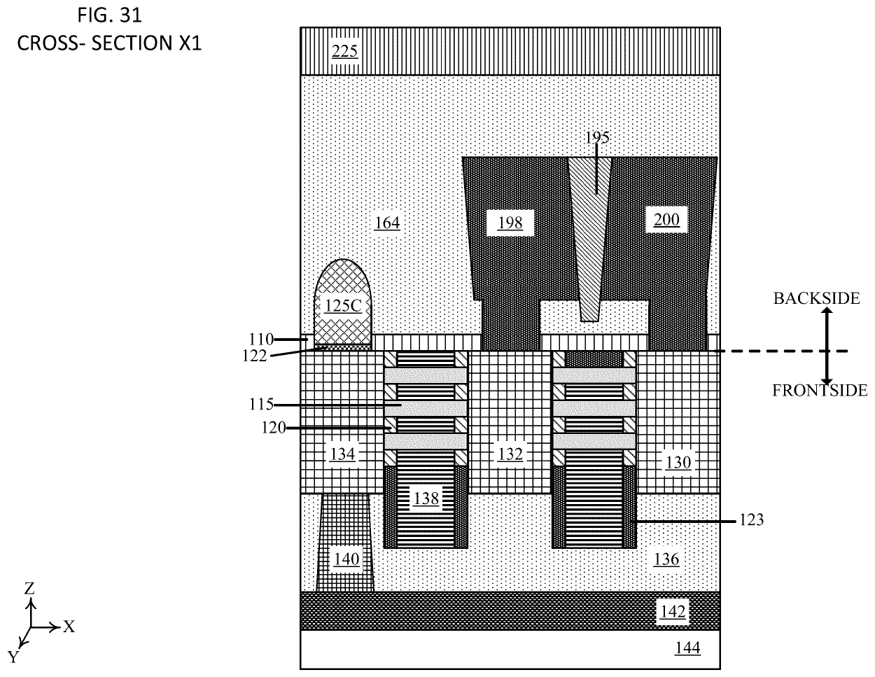

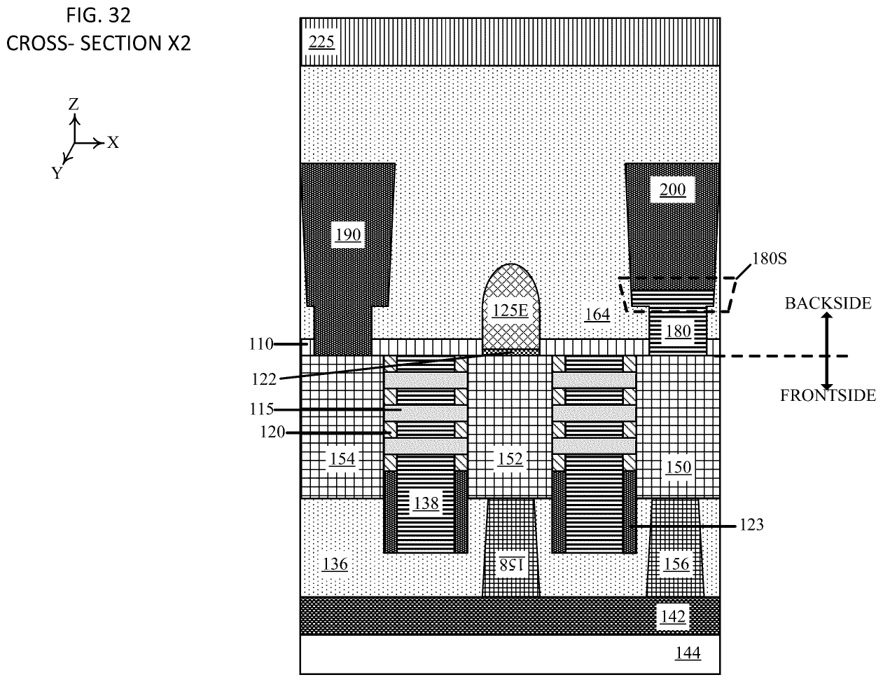

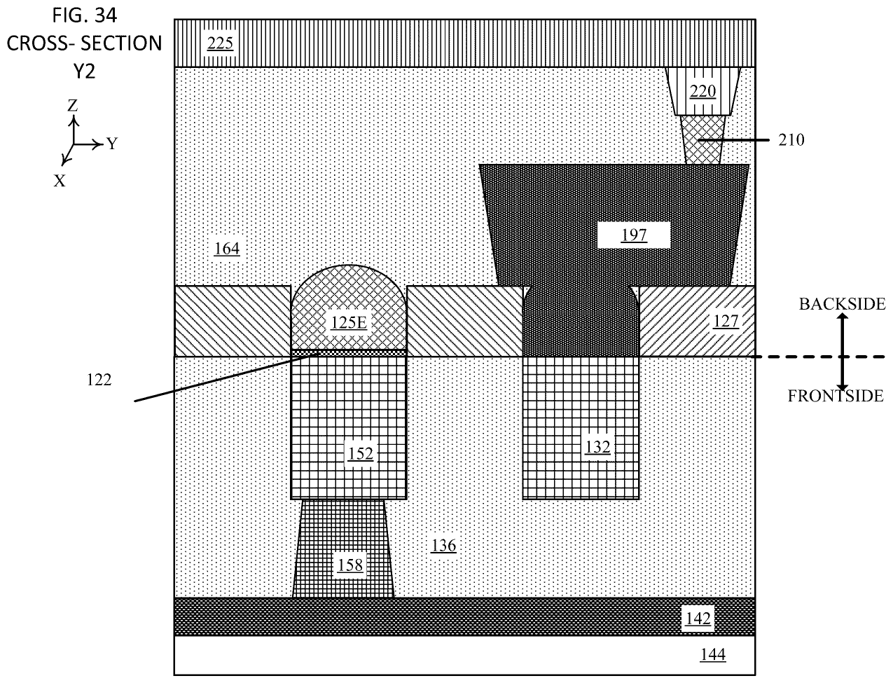

FIGS. 31, 32, 33, and 34 illustrate the processing stage after increasing the height of the backside interlayer dielectric layer 164, formation of a first and second metal line 215, 220, and formation of a backside interconnect 225. The height of the backside interlayer dielectric layer 164 is increased so that the backside interlayer dielectric layer 164 extends on top of the first contact via (not shown), the second contact via 205, and the third contact via 210. A plurality of trenches (not shown) are formed in the backside interlayer dielectric layer 164, where one of the trenches (not shown) is formed over the first contact via (not shown) and the second contact via 205 and one of the trenches (not shown) is formed over the third contact via 210. A metallization process fills these trenches (not shown) to form a first metal line 220 and a second metal line 215. The first metal line 220 and the second metal line 215 can be for example, power rails, clock signal, ground, time, or another type of line. For example, the first metal line 220 can be a VDD power rail and the second metal line 215 can be a VSS power rail. The first source/drain bypass contact 200 extends along the backside region of the second FET (i.e., under the fourth source/drain 150) to connect with the second metal line 215, while the first source/drain bypass contact 200 is on the same level as the second source/drain contact 197 that is connected to the first metal line 2220 that is located adjacent to the first nanosheet FET. A backside interconnect 225 is formed on top of the backside interlayer dielectric layer 164, the first metal line 220, and the second metal line 215. The backside interconnect 225 can be, for example, a backside-power-distribution-network (BSPDN). The backside interconnect 225 can include one or more layers or level, one or more metal lines, and one or more connecting vias.

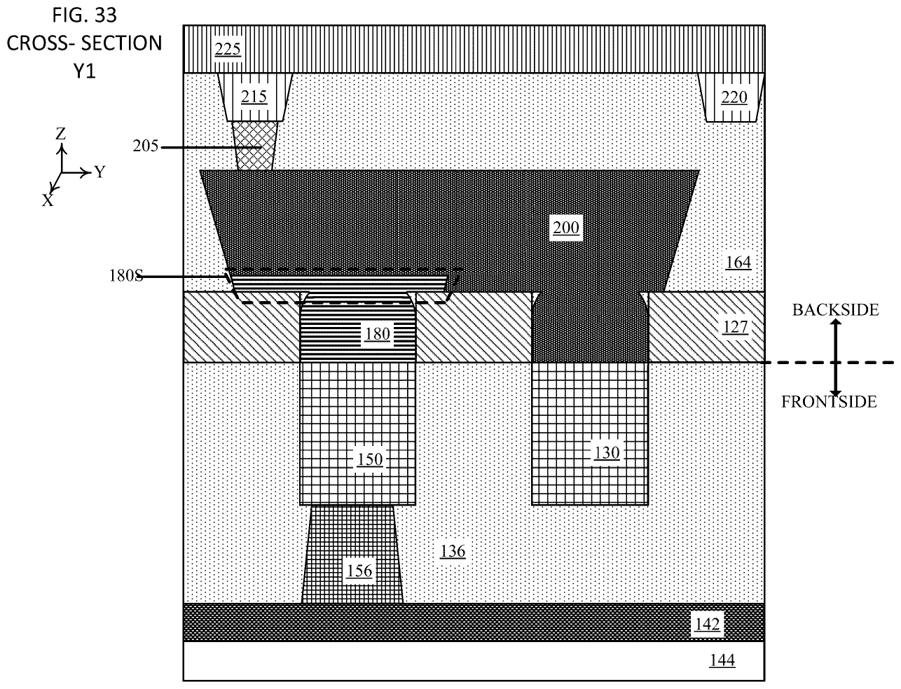

A microelectronic structure includes a first nanosheet FET that includes a first and second source/drain 130, 132. A second nanosheet FET located adjacent to the first nanosheet FET. A first backside contact 200 connected to the first source/drain 130 and the first backside contact 200 extends through the backside region of the second nanosheet FET (see, for example, FIG. 33). A second backside contact 197 connected to the second source/drain 132. The first backside contact 200 and the second backside contact 197 are located on the same level.

A first metal line 220 located adjacent to the first nanosheet FET and a second metal line 215 located adjacent to the second nanosheet FET. The second backside contact 197 is connected to the first metal line 220. The first backside contact 200 is connected to the second metal line 215.

The second nanosheet FET includes a third source/drain 150. The first backside contact 200 extends through a backside region of the third source/drain 150. The first backside contact 200 bypasses the third source/drain 150.

A microelectronic structure includes a first nanosheet FET that includes a first and second source/drain 130, 132. A second nanosheet FET located adjacent to the first nanosheet FET. A first backside contact 200 connected to the first source/drain 130 and the first backside contact 200 extends through the backside region of the second nanosheet FET (see, for example, FIG. 33). A second backside contact 197 connected to the second source/drain 132. The first backside contact 200 and the second backside contact 197 are located on the same level. A dielectric pillar 195 (or shared contact cut 195) located between the first backside contact 200 and the second backside contact 197.

A first metal line 220 located adjacent to the first nanosheet FET and a second metal line 215 located adjacent to the second nanosheet FET. The second backside contact 197 is connected to the first metal line 220. The first backside contact 200 is connected to the second metal line 215.

The second nanosheet FET includes a third source/drain 150. The first backside contact 200 extends through a backside region of the third source/drain 150. The first backside contact 200 bypasses the third source/drain 150.

The first backside contact 200 is in direct contact with a first side of the dielectric pillar 195 (or shared contact cut 195) and the second backside contact 197 is in direct contact with a second side of the dielectric pillar 195 (or shared contact cut 195). The first side of the dielectric pillar 195 (or shared contact cut 195) and the second side of the dielectric pillar 195 (or shared contact cut 195) are different sides.

A microelectronic structure includes a first nanosheet FET that includes a first and second source/drain 130, 132. A second nanosheet FET located adjacent to the first nanosheet FET includes a third source/drain 150. A dielectric cap 180 (or backside isolation layer 180) is located on the backside of the third source/drain 150. A first backside contact 200 connected to the first source/drain 130 and the first backside contact 200 extends through the backside region of the second nanosheet FET (see, for example, FIG. 33). A second backside contact 197 connected to the second source/drain 132. The first backside contact 200 and the second backside contact 197 are located on the same level. A dielectric pillar 195 (or shared contact cut 195) located between the first backside contact 200 and the second backside contact 197.

A first metal line 220 located adjacent to the first nanosheet FET and a second metal line 215 located adjacent to the second nanosheet FET. The second backside contact 197 is connected to the first metal line 220, and wherein the first backside contact 200 is connected to the second metal line 215. The first backside contact 200 extends through a backside region of the third source/drain 150. The first backside contact 200 contacts the dielectric cap 180 (or backside isolation layer 180) to bypasses the third source/drain 150.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet FET that includes a first and second source/drain;
a second nanosheet FET located adjacent to the first nanosheet FET;
a first backside contact connected to the first source/drain, wherein the first backside contact extends through a backside region of the second nanosheet FET; and
a second backside contact connected to the second source/drain, wherein the first backside contact and the second backside contact are located on the same level.

2. The microelectronic structure of claim 1, further comprising:
a first metal line located adjacent to the first nanosheet FET; and
a second metal line located adjacent to the second nanosheet FET.

3. The microelectronic structure of claim 2, wherein the second backside contact is connected to the first metal line.

4. The microelectronic structure of claim 3, wherein the first backside contact is connected to the second metal line.

5. The microelectronic structure of claim 1, wherein the second nanosheet FET includes a third source/drain.

6. The microelectronic structure of claim 5, wherein the first backside contact extends through a backside region of the third source/drain.

7. The microelectronic structure of claim 6, wherein the first backside contact bypasses the third source/drain.

8. A microelectronic structure comprising:
a first nanosheet FET that includes a first and second source/drain;
a second nanosheet FET located adjacent to the first nanosheet FET;
a first backside contact connected to the first source/drain, wherein the first backside contact extends through a backside region of the second nanosheet FET;
a second backside contact connected to the second source/drain, wherein the first backside contact and the second backside contact are located on the same level; and
a dielectric pillar located between the first backside contact and the second backside contact.

9. The microelectronic structure of claim 8, further comprising:
a first metal line located adjacent to the first nanosheet FET; and
a second metal line located adjacent to the second nanosheet FET.

10. The microelectronic structure of claim 9, wherein the second backside contact is connected to the first metal line.

11. The microelectronic structure of claim 10, wherein the first backside contact is connected to the second metal line.

12. The microelectronic structure of claim 8, wherein the second nanosheet FET includes a third source/drain.

13. The microelectronic structure of claim 12, wherein the first backside contact extends through a backside region of the third source/drain.

14. The microelectronic structure of claim 13, wherein the first backside contact bypasses the third source/drain.

15. The microelectronic structure of claim 8, wherein the first backside contact is in direct contact with a first side of the dielectric pillar, wherein the second backside contact is in direct contact with a second side of the dielectric pillar, wherein the first side of the dielectric pillar and the second side of the dielectric pillar are different sides.

16. A microelectronic structure comprising:
a first nanosheet FET that includes a first and second source/drain;
a second nanosheet FET located adjacent to the first nanosheet FET includes a third source/drain;
a dielectric cap is located on a backside of the third source/drain;
a first backside contact connected to the first source/drain, wherein the first backside contact extends through a backside region of the second nanosheet FET;
a second backside contact connected to the second source/drain, wherein the first backside contact and the second backside contact are located on the same level; and
a dielectric pillar located between the first backside contact and the second backside contact.

17. The microelectronic structure of claim 16, further comprising:
a first metal line located adjacent to the first nanosheet FET; and
a second metal line located adjacent to the second nanosheet FET.

18. The microelectronic structure of claim 17, wherein the second backside contact is connected to the first metal line, and wherein the first backside contact is connected to the second metal line.

19. The microelectronic structure of claim 18, wherein the first backside contact extends through a backside region of the third source/drain.

20. The microelectronic structure of claim 19, wherein the first backside contact contacts the dielectric cap to bypasses the third source/drain.
